(19) United States
(12) Patent Application Publication
(10) Pub. No.: US 2025/0383385 A1
(43) Pub. Date: Dec. 18, 2025

(54) INTERCONNECTION STRUCTURE IMPEDANCE MEASUREMENT CIRCUIT AND MEASUREMENT DEVICE, AND MEASUREMENT METHOD

(71) Applicant: SANECHIPS TECHNOLOGY CO., LTD., Nanshan District, Shenzhen, Guangdong (CN)

(72) Inventors: Xiaopeng WU, Shenzhen, Guangdong (CN); Niuyi SUN, Shenzhen, Guangdong (CN); Dan YANG, Shenzhen, Guangdong (CN); Na MEI, Shenzhen, Guangdong (CN); Tuobei SUN, Shenzhen, Guangdong (CN)

(21) Appl. No.: 18/875,789

(22) PCT Filed: Jun. 20, 2023
(86) PCT No.: PCT/CN2023/101489

§ 371 Date: Dec. 17, 2024

(30) Foreign Application Priority Data
Jun. 30, 2022 (CN) 202210779103.7

(51) Int. Cl. G01R 27/16; G01R 31/70

(52) U.S. Cl. CPC G01R 27/16; G01R 31/70

(57) ABSTRACT

The present disclosure provides an interconnection structure impedance measurement circuit, in which a Wheatstone bridge structure is optimized by using three branches connected in parallel where interconnection structures to be measured in one branch are connected in series while two resistors in the other two branches are connected in series. The branch with the interconnection structures and one of the other two branches are controlled to be simultaneously closed to measure a voltage between the two branches that are closed, and an impedance of two interconnection structures is calculated according to a current introduced into the interconnection structure impedance measurement circuit, the measured voltage, and resistances in the branches. The present disclosure further provides interconnection structure impedance measurement device and method.

### CROSS-REFERENCE TO RELATED APPLICATIONS

The present disclosure claims the priority of Chinese patent application CN202210779103.7 titled “INTERCONNECTION STRUCTURE IMPEDANCE MEASUREMENT CIRCUIT AND MEASUREMENT DEVICE, AND MEASUREMENT METHOD” filed with the CNIPA on Jun. 30, 2022, the entire contents of which are incorporated herein by reference.

### TECHNICAL FIELD

Embodiments of the present disclosure of relate to, but are not limited to, the technical field of circuit testing and reliability testing, and in particular, to an interconnection structure impedance measurement circuit and a measurement device, and a measurement method.

### BACKGROUND

Accurate measurement of tiny resistive impedances has been a focus of various industries. Especially for interconnection metal lines and interconnection pads, the accurate measurement of the resistance plays an important role in evaluating the overall system performance and the welding quality. As for the reliability evaluation of a single interconnection structure, taking an electromigration test as an example, there is still no effective method for accurately monitoring a resistance of a single pad structure in a long-term aging test.

To accurately measure the resistive impedances of various small structures such as interconnection metal lines, researchers have proposed various ideas and methods, among which the four-point probe method is a well-known accurate measurement method. However, the four-point probe method still has some drawbacks in application. For example, the resistive impedance cannot be measured in real time in a large scale, and the measurement is relatively complex, involving higher cost and less convenient manual measurement. The classical Wheatstone bridge structure can also be used in measurement of tiny resistances. However, there are many limitations to use of the Wheatstone bridge structure. For example, three of the resistive impedances are required to be known, and an appropriate resistive impedance has to be selected to balance the bridge. Then, the unknown resistive impedance is obtained by solving an equation system, which makes it difficult to meet the requirements and limits the application scenarios. Therefore, there is an urgent need for an apparatus or method which can implement large-scale, automated, easy and accurate measurement of an impedance of an interconnection structure.

### SUMMARY

The present disclosure provides an interconnection structure impedance measurement circuit and a measurement device, and a measurement method.

In a first aspect, an embodiment of the present disclosure provides an interconnection structure impedance measurement circuit, including: a first branch, a second branch and a third branch connected in parallel, wherein the first branch includes a first interconnection structure, a second interconnection structure and a first switch connected in series, the second branch includes a first resistor, a second resistor and a second switch connected in series, and the third branch includes a third resistor, a fourth resistor and a third switch connected in series; and an impedance of the first interconnection structure and an impedance of the second interconnection structure are determined from a first voltage between the first branch and the second branch, a second voltage between the first branch and the third branch, the first resistor, the second resistor, the third resistor, the fourth resistor, and a first current introduced into the interconnection structure impedance measurement circuit, wherein the first voltage is detected when the first switch and the second switch are closed and the third switch is open, and the second voltage is detected when the first switch and the third switch are closed and the second switch is open.

In another aspect, an embodiment of the present disclosure further provides an interconnection structure impedance measurement device, including: a constant current source, a voltage detection module, a control module and the interconnection structure impedance measurement circuit as described above. The constant current source is connected to the first branch, the second branch and the third branch, and configured to provide, under the condition that the first switch and the second switch are closed and the third switch is open, or that the first switch and the third switch are closed and the second switch is open, a first current for the interconnection structure impedance measurement circuit: the voltage detection module is connected with the first branch, the second branch and the third branch, respectively, and configured to detect, under the condition that the first switch and the second switch are closed and the third switch is open, a first voltage between the first branch and the second branch; and detect, under the condition that the first switch and the third switch are closed and the second switch is open, a second voltage between the first branch and the third branch; and the control module is configured to control the constant current source to provide the first current for the interconnection structure impedance measurement circuit, and control the closing or opening of the first switch, the second switch, and the third switch; and acquire the first voltage and the second voltage detected by the voltage detection module, and calculate an impedance of the first interconnection structure and an impedance of the second interconnection structure according to the first resistor, the second resistor, the third resistor, the fourth resistor, the first voltage, the second voltage and the first current.

In another aspect, an embodiment of the present disclosure further provides an interconnection structure impedance measurement method applied to the interconnection structure impedance measurement device as described above, the method including: providing a first current for the interconnection structure impedance measurement circuit: controlling the interconnection structure impedance measurement circuit to be in a first state, and detecting a first voltage between the first branch and the second branch; wherein in the first state, the first switch and the second switch are closed and the third switch is open: controlling the interconnection structure impedance measurement circuit to switch from the first state to a second state, and detecting a second voltage between the first branch and the third branch: wherein in the second state, the first switch and the third switch are closed and the second switch is open; and stopping providing the first current for the interconnection structure impedance measurement circuit, and calculating an impedance of the first interconnection structure and an impedance of the second interconnection structure according to the first resistor, the second resistor, the third resistor, the fourth resistor, the first voltage, the second voltage and the first current.

In another aspect, an embodiment of the present disclosure further provides an interconnection structure impedance measurement method applied to the interconnection structure impedance measurement device as described above, the method including: measuring an impedance of the second interconnection structure in the method described above: controlling the interconnection structure impedance measurement circuit to switch from the second state to a third state in which the first switch is closed and the second switch and the third switch are open: providing a second current for the interconnection structure impedance measurement circuit within a preset time period, to increase current stress and accelerate degradation of the interconnection structure; and measuring an impedance of the second interconnection structure in the method described above, comparing the impedance with a preset failure impedance value, and stopping measurement when the impedance of the second interconnection structure reaches the failure impedance value.

### BRIEF DESCRIPTION OF DRAWINGS

FIG. 1 is a schematic diagram of an interconnection structure impedance measurement circuit according to an embodiment of the present disclosure;

FIG. 2 is a schematic diagram of a physical structure corresponding to the measurement circuit of FIG. 1:

FIG. 3 is a schematic circuit diagram of resistance measurement with a conventional Wheatstone bridge:

FIG. 4 is a schematic diagram of an interconnection structure impedance measurement circuit according to another embodiment of the present disclosure:

FIG. 5 is a schematic diagram of a physical structure corresponding to the measurement circuit of FIG. 4:

FIG. 6 is a schematic diagram of a measurement circuit packaged on a measurement device according to an embodiment of the present disclosure:

FIG. 7 is a schematic diagram of a measurement circuit packaged on a PCB according to an embodiment of the present disclosure:

FIG. 8 is a schematic structural diagram of an interconnection structure impedance measurement device according to an embodiment of the present disclosure:

FIG. 9 is a schematic structural diagram of an interconnection structure impedance measurement device according to another embodiment of the present disclosure:

FIG. 10 is a schematic flowchart of an interconnection structure impedance measurement method according to an embodiment of the present disclosure; and

FIG. 11 is a schematic flowchart of an interconnection structure impedance measurement method according to another embodiment of the present disclosure.

### DETAIL DESCRIPTION OF EMBODIMENTS

Exemplary embodiments will be described more sufficiently below with reference to the accompanying drawings, but which may be embodied in different forms and should not be construed as limited to the embodiments set forth herein. Rather, these embodiments are provided so that the present disclosure will be thorough and complete, and will fully convey the scope of the present disclosure to those skilled in the art.

As used herein, the term “and/or” includes any and all combinations of one or more of the associated listed items.

The terminology used herein is for the purpose of describing specific embodiments only and is not intended to limit the present disclosure. As used herein, the singular forms “a”, “an” and “the” are intended to include the plural forms as well, unless the context clearly indicates otherwise. It will be further understood that as used herein, the terms “comprise” and/or “consist of . . . ” specify the presence of stated features, integers, steps, operations, elements, and/or components, but do not preclude the presence or addition of one or more other features, integers, steps, operations, elements, components, and/or groups thereof.

Embodiments described herein may be described with reference to plan and/or sectional views in idealized representations of the present disclosure. Accordingly, the example illustrations may be modified in accordance with the manufacturing process and/or the tolerance. Therefore, the embodiments are not limited to the embodiments shown in the drawings, but further include modifications of configurations formed based on a manufacturing process. Therefore, the regions illustrated in the figures have schematic properties, and the shapes of the regions shown in the figures illustrate specific shapes of regions of elements, but are not intended to be limitative.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the existing art and the present disclosure, and will not be interpreted in an idealized or overly formal sense unless expressly so defined herein.

Since interconnection metal lines and interconnection pads typically have tiny structures and good metallic conductivity, how to accurately measure the resistance value of the resistor therein has always been an industry pain point. Further, in a reliability experiment, the interconnection structure is also a focus of the experiment. Under long-term temperature/current stress, the degree of degradation or failure of the interconnection structure is often determined through changes in resistance value of the interconnection structure. Since the interconnection structure itself has a tiny resistance, changes in the resistance are also very tiny. Therefore, it is very important to accurately monitor the impedance of the interconnection structure in real time for reliability experiments. The four-point probe method for accurate measurement of interconnection lines and pads can reach the highest accuracy so far, but the measurement process is complex and cannot implement real-time monitoring of the resistance value, while involving high cost. The classical Wheatstone bridge can measure a resistance value with relatively high accuracy, but resistance values of three of the resistors are required to be known, which limits the practicability and makes it difficult to be applied in a large scale.

To solve the above problem, an embodiment of the present disclosure provides an interconnection structure impedance measurement circuit. As shown in FIG. 1, the interconnection structure impedance measurement circuit includes a first branch, a second branch and a third branch connected in parallel, where the first branch includes a first interconnection structure, a second interconnection structure and a first switch K1 connected in series, the second branch includes a first resistor R1, a second resistor R2 and a second switch K2 connected in series, and the third branch includes a third resistor R1′, a fourth resistor R2′ and a third switch K3 connected in series.

An impedance R3 of the first interconnection structure and an impedance R4 of the second interconnection structure are determined from a first voltage Vg between the first branch and the second branch, a second voltage Vg′ between the first branch and the third branch, the first resistor R1, the second resistor R2, the third resistor R1′, the fourth resistor R2′, and a first current I introduced into the interconnection structure impedance measurement circuit.

The first voltage Vg is detected when the first switch K1 and the second switch K2 are closed and the third switch K3 is open, and the second voltage Vg′ is detected when the first switch K1 and the third switch K3 are closed and the second switch K2 is open.

According to the interconnection structure impedance measurement circuit according to the embodiment of the present disclosure, a Wheatstone bridge structure is optimized, and three branches connected in parallel are used, where interconnection structures to be measured in one branch are connected in series, while two resistors in the other two branches are connected in series. The branch with the interconnection structures and one of the other two branches are controlled to be simultaneously turned on to measure a voltage between the two branches that are turned on, and an impedance of two interconnection structures is calculated according to a current introduced into the interconnection structure impedance measurement circuit, the measured voltage, and resistances in the branches. According to the embodiments of the present disclosure, the impedance of the interconnection structures can be conveniently and accurately measured in a large scale, and the impedance of a single interconnection structure in a reliability experiment can be accurately monitored in real time.

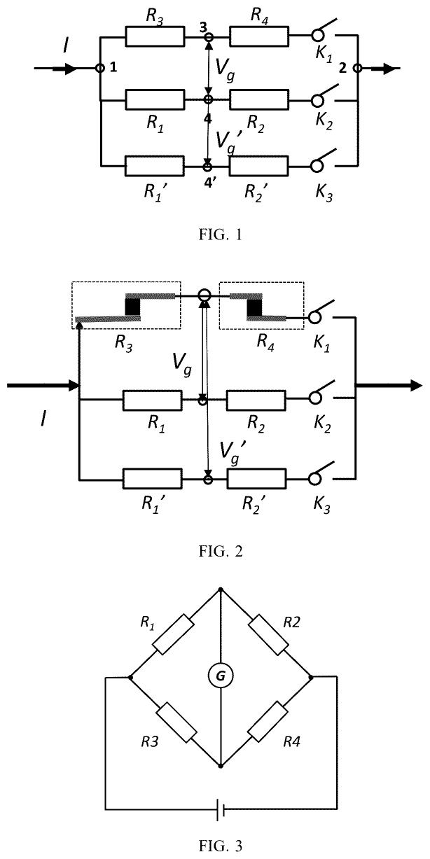

FIG. 2 is a schematic diagram of a physical structure corresponding to the interconnection structure impedance measurement circuit of FIG. 1. As shown in FIG. 2, the first interconnection structure and the second interconnection structure are connected to a printed circuit board (PCB) and an IC substrate, respectively, via ball grid array (BGA) balls, for example.

FIG. 3 is a schematic circuit diagram of resistance measurement with a conventional Wheatstone bridge. As shown in FIG. 3, resistance values of R1, R2, and R3 are known, while R4 is a resistor to be measured. G represents a galvanometer, and when a pointer of the galvanometer points to zero, the bridge is balanced and a resistance value of R4 can be calculated by R1*R4=R2*R3.

Referring to FIGS. 1 and 2, R3 is an impedance of the first interconnection structure, R4 is an impedance of the second interconnection structure, R1 and R2 are known resistors, and R1′ and R2′ are also known resistors. I is an input current, Vg is a voltage difference between node 3 and node 4, and Vg′ is a voltage difference between node 3 and node 4′. After a plurality of iterations, values of the impedance R3 of the first interconnection structure and the impedance R4 of the second interconnection structure can be calculated by solving a system of nonlinear equations simultaneously.

According to the Kirchhoff's law, it is obtained that:

$${V}_{g} = IR ( \frac{{R}_{1}}{{R}_{1} + {R}_{2}} - \frac{{R}_{3}}{{R}_{3} + {R}_{4}} ) \qquad ( 1 )$$

$${V}_{g}^{′} = {IR}^{′} ( \frac{{R}_{1}^{′}}{{R}_{1}^{′} + {R}_{2}^{′}} - \frac{{R}_{3}}{{R}_{3} + {R}_{4}} ) \qquad ( 2 )$$

$$R = \frac{( {R}_{1} + {R}_{2} ) ( {R}_{3} + {R}_{4} )}{{R}_{1} + {R}_{2} + {R}_{3} + {R}_{4}} \qquad ( 3 )$$

$${R}^{′} = \frac{( {R}_{1}^{′} + {R}_{2}^{′} ) ( {R}_{3} + {R}_{4} )}{{R}_{1}^{′} + {R}_{2}^{′} + {R}_{3} + {R}_{4}} \qquad ( 4 )$$

where R is a resistor in the second branch, and R′ is a resistor in the third branch.

The above equations (1), (2), (3) and (4) are solved simultaneously to obtain:

$${R}_{4} = \frac{{V}_{g} ( {R}_{1} + {R}_{2} ) ( {V}_{g}^{′} + {IR}_{2}^{′} ) - {V}_{g}^{′} ( {R}_{1}^{′} + {R}_{2}^{′} ) ( {V}_{g} + {IR}_{2} )}{I [ {V}_{g}^{′} ( {R}_{1} + {R}_{2} ) - {V}_{g} ( {R}_{1}^{′} + {R}_{2}^{′} ) + I ( {R}_{1} {R}_{2}^{′} - {R}_{1}^{′} {R}_{2} ) ]} \qquad ( 5 )$$

$${R}_{3} = \frac{{V}_{g} ( {R}_{1} + {R}_{2} ) ( {IR}_{1}^{′} + {V}_{g}^{′} ) - {V}_{g}^{′} ( {R}_{1}^{′} + {R}_{2}^{′} ) ( {IR}_{1} + {V}_{g} )}{I [ {V}_{g}^{′} ( {R}_{1} + {R}_{2} ) - {V}_{g} ( {R}_{1}^{′} + {R}_{2}^{′} ) + I ( {R}_{1} {R}_{2}^{′} - {R}_{1}^{′} {R}_{2} ) ]} \qquad ( 6 )$$

It should be noted that there is no further requirement on selections of resistance values of the four resistors R1, R2, R1′ and R2′. However, in the scenario of measuring an impedance of a tiny structure, the measurement precision can be further improved by controlling such that R1/R2≈R1′/R2′.

In some embodiments, the first resistor R1 has a resistance value that is not equal to a resistance value of the third resistor R1′, and the second resistor R2 has a resistance value that is not equal to a resistance value of the fourth resistor R2′.

The embodiment of the present disclosure may be applied to various technical fields like electronic packaging, reliability testing, fine measurement, or the like. In the manufacturing process of electronic packaging, there are lots of welding and interconnection occasions, and the quality of the interconnection structure will directly influence the quality of the product. Therefore, rapid evaluation of the welding quality of the interconnection structure has self-evident importance. Poor welding will be reflected in an increased resistance, and the interconnection structure impedance measurement circuit provided in the embodiment of the present disclosure can be used for rapid detection of an impedance of the interconnection structure, and thereby used as a detection tool for monitoring changes in the production process in real time. Likewise, throughout the manufacturing process of the chip, the resistance value of the interconnection structure is difficult to determine due to a contact resistance thereof. Then, the interconnection structure impedance measurement circuit provided in the embodiment of the present disclosure can be also used for rapid and accurate measurement of an impedance of the tiny interconnection structure, providing important application value in terms of performance evaluation of the whole system and the like.

In reliability testing, changes in the impedance value are monitored continuously for most occasions. Therefore, the interconnection structure impedance measurement circuit provided in the embodiment of the present disclosure may be improved to implement impedance monitoring of a single interconnection structure in a reliability experiment.

In some embodiments, the impedance R3 of the first interconnection structure is in units of milliohms. In other words, the first interconnection structure in the interconnection structure impedance measurement circuit is designed as an interconnection structure having a smaller impedance, thereby forming a single interconnection structure including the second interconnection structure in the first branch.

The first interconnection structure with the lower impedance may be implemented in a variety of ways. Illustratively, the first interconnection structure may include at least two fifth resistors connected in parallel and having the same resistance value which is the same as a resistance value of the second interconnection structure: or, the first interconnection structure may be implemented by a wire.

In an embodiment of the present disclosure, as shown in FIGS. 4 and 5, the first interconnection structure includes three fifth resistors R5 connected in parallel. In fact, the number of fifth resistors R5 connected in parallel may further increase, and the more fifth resistors R5 are provided, the more accurate measurement of the impedance of the single interconnection structure (i.e., the impedance R4 of the second interconnection structure) can be obtained. It should be noted that the impedance R3 of the first interconnection structure is a resulting impedance when the fifth resistors are connected in parallel.

In some embodiments, in the case where the first interconnection structure includes n fifth resistors R5 connected in parallel (where n is an integer greater than or equal to 2), the resistance value of the second resistor R2 is n times the resistance value of the first resistor R1, and the resistance value of the fourth resistor R2′ is n times the resistance value of the third resistor R1′. In other words, selection of resistance values of the first resistor R1, the second resistor R2, the third resistor R1′, and the fourth resistor R2′ in the second and third branches are correlated with the number of fifth resistors R5 connected in parallel in the first interconnection structure. FIG. 4 shows that three fifth resistors R5 connected in parallel are then connected in series with another single interconnection structure (i.e., the second interconnection structure R4), so the impedance R4 of the second interconnection structure is about 3 times the impedance of the three fifth resistors R5.

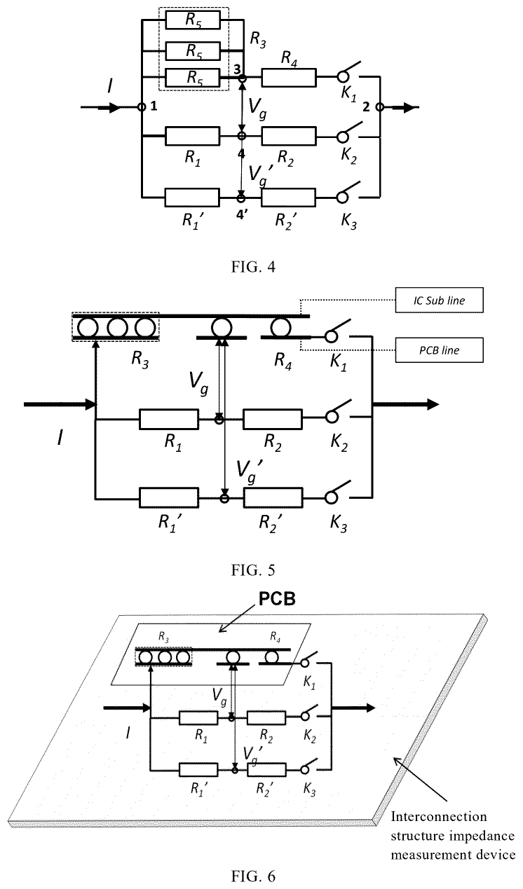

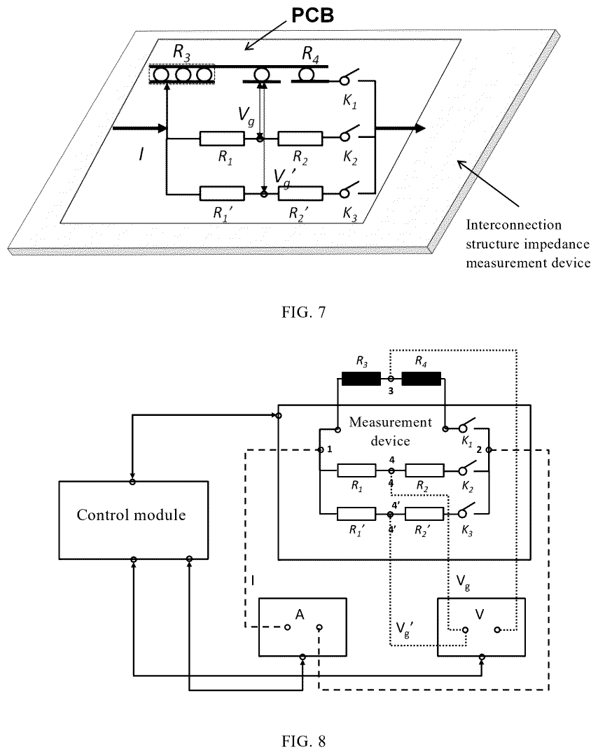

FIGS. 6 and 7 show two application scenarios of the interconnection structure impedance measurement circuit, and the two measurement design schemes of FIGS. 6 and 7 may be adopted for different measurement requirements.

As shown in FIG. 6, the interconnection structure impedance measurement circuit is packaged on an interconnection structure impedance measurement device, the PCB is connected to the interconnection structure impedance measurement device through the first interconnection structure and the second interconnection structure, and the interconnection structure impedance measurement device is used to measure impedances of the two interconnection structures. In the scenario shown in FIG. 6, the PCB layout design is relatively simple and economical, but has relatively high requirements on the interconnection structure impedance measurement device.

As shown in FIG. 7, the interconnection structure impedance measurement circuit is integrated on the PCB, and when the impedance R3 of the first interconnection structure and the impedance R4 of the second interconnection structure are measured, the interconnection structure impedance measurement device only needs to provide current. Therefore, in the scenario shown in FIG. 7, the measurement system is simple to build and convenient for measurement, but the PCB layout design is more difficult and consumptive, involving high cost.

An embodiment of the present disclosure further provides an interconnection structure impedance measurement device, which, as shown in FIG. 8, includes: a constant current source (A), a voltage detection module (V), a control module and an interconnection structure impedance measurement circuit, where the interconnection structure impedance measurement circuit is an interconnection structure impedance measurement circuit as shown in FIG. 1.

The constant current source is connected to the first branch, the second branch and the third branch, and configured to provide, under the condition the first switch K1 and the second switch K2 are closed and the third switch K3 is open, or that the first switch K1 and the third switch K3 are closed and the second switch K2 is open, a first current for the interconnection structure impedance measurement circuit.

The voltage detection module is connected with the first branch, the second branch and the third branch, respectively, and configured to detect, under the condition the first switch K1 and the second switch K2 are closed and the third switch K3 is open, a first voltage Vg between the first branch and the second branch; and detect, under the condition that the first switch K1 and the third switch K3 are closed and the second switch K2 is open, a second voltage Vg′ between the first branch and the third branch.

The control module is configured to control the constant current source to provide the first current for the interconnection structure impedance measurement circuit, and control the opening or closing of the first switch K1, the second switch K2, and the third switch K3; and acquire the first voltage Vg and the second voltage Vg′ detected by the voltage detection module, and calculate an impedance R3 of the first interconnection structure and an impedance R4 of the second interconnection structure according to the first resistor R1, the second resistor R2, the third resistor R1′, the fourth resistor R2′, the first voltage Vg, the second voltage Vg′ and the first current.

The interconnection structure impedance measurement device includes one constant current source, two voltmeters, three switches, two interconnection structures, and four resistors, where the two interconnection structures are resistors to be measured (R3 and R4), and resistance values of the four resistors (R1, R2, R1′ and R2′) are known. There are three parallel branches, where a first branch includes one first switch K1, a first interconnection structure and a second interconnection structure, a second branch includes one second switch K2 and two fixed resistors R1 and R2, a third branch includes a third switch K3 and two fixed resistors R1′ and R2′, and one voltmeter V is connected between the first branch and the second branch, while the other is connected between the first branch and the third branch. When the impedances R3 and R4 of the interconnection structures are measured, the first current provided by the constant current source is introduced. The first voltage Vg and the second voltage Vg′ are obtained through measurement and substituted into the above equations (5) and (6), so that the impedance R3 of the first interconnection structure and the impedance R4 of the second interconnection structure can be calculated simultaneously. Further, real-time monitoring of the impedance R3 of the first interconnection structure and the impedance R4 of the second interconnection structure is realized by controlling the opening or closing of the switches (K1, K2 and K3) by the control module.

The principle of implementing real-time impedance monitoring of the interconnection structure may be also suitable for accurate measurement of a resistive impedance of a tiny structure, which usually does not need real-time switching by the control module since tiny structures often have substantially the same core circuit structures, and involves solving for R3 and R4 by measuring and substituting Vg and Vg′ into equations (5) and (6) so that the resistance is obtained through equations by measuring a voltage instead of directly measuring the resistive impedance, thereby improving the accuracy. By selecting the resistance values of the four resistors R1, R2, R1′ and R2′, the measurement precision can be further improved by controlling such that R1/R2≈R1′/R2′.

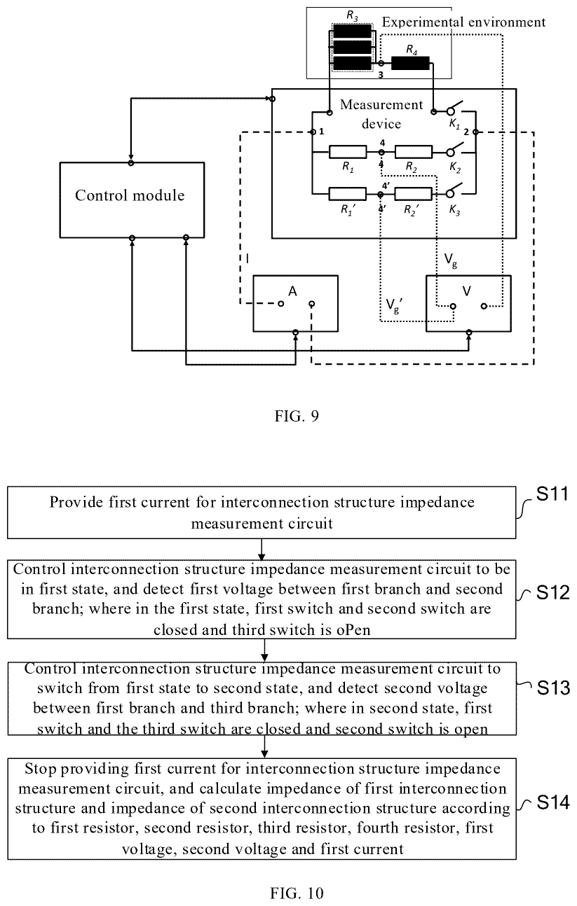

In some embodiments, as shown in FIG. 9, in the case where the interconnection structure impedance measurement circuit is the interconnection structure impedance measurement circuit shown in FIG. 4, the constant current source is further configured to provide a second current for the interconnection structure impedance measurement circuit under the condition that the first switch K1 is closed and the second switch K2 and the third switch K3 are open, where the second current is greater than the first current. In other words, the constant current source provides current stress in a power supply mode in which the first branch is on and the second switch and the third switch are off.

The interconnection structure impedance measurement device includes one constant current source, two voltmeters, three switches, an interconnection structure formed by three resistors (R5) connected in parallel, and four fixed resistors. The resistors connected in parallel are of the same type and produced in the same batch, so as to ensure that the resistance values of the resistors are substantially the same, and resistance values of the four fixed resistors (R1, R2, R1′ and R2′) are known. One voltmeter V is connected between the first branch and the second branch, while the other is connected between the first branch and the third branch. There are three parallel branches, where a first branch includes one first switch K1, a first interconnection structure formed by a plurality of resistors connected in parallel, and a second interconnection structure (single interconnection structure), a second branch includes one second switch K2 and two fixed resistors R1 and R2, and a third branch includes a third switch K3 and two fixed resistors R1′ and R2′, where R2′ is about 3 times of R1′, and R1′ and R2′ have values following the same rule as, but not completely equal to, R1 and R2. In the embodiment of the present disclosure, the case where three fifth resistors are connected in parallel to obtain a first interconnection structure is taken as an example for illustration, that is, n=3, and correspondingly, R2′ is about 3 times of R1′. It should be noted that the impedance R4 of the second interconnection structure can be calculated through equation (5) as long as n≥2, and a larger value of n will lead to a higher measurement precision. When the impedance of the single interconnection structure (i.e., the impedance R4 of the second interconnection structure) is measured in a reliability experiment, the first interconnection structure and the second interconnection structure are placed in an aging experimental environment, and the second current provided by the constant current source is introduced. The first voltage Vg and the second voltage Vg′ are obtained through measurement and substituted into equation (5), so that the impedance R4 of the single interconnection structure can be calculated. Further, real-time monitoring of the impedance R4 of the single interconnection structure is realized by controlling the closing or opening of the switch circuits by the control module. The experiment is terminated when R4 reaches a failure judgment standard, and then accurate failure time of the single interconnection structure can be obtained, which can further facilitate prediction of the characteristic life of components and the whole system.

In the reliability experiment of the interconnection structure, the interconnection structure is subjected to accelerated degradation by applying temperature/current stress, whereas the degradation process is actually a process of damage generation inside the interconnection structure, such as occurrence of holes, fracture, generation of metal compounds and the like. The damage may cause an increased resistance in the interconnection structure, and by measuring and substituting Vg and Vg′ into equations (5) and (6), values of the impedance R3 of the first interconnection structure and the impedance R4 of the second interconnection structure can be calculated, thereby implementing monitoring of the impedance of the interconnection structure. The first interconnection structure is implemented by a plurality of resistors connected in parallel, so that the current flowing through the first interconnection structure is smaller than the current flowing through the second interconnection structure, and thus, the degradation of the first interconnection structure under current stress is slower than that of the second interconnection structure. Assuming that three copper resistors are connected in parallel to form the first interconnection structure, and a general current density index n=2, then according to the Blake equation, a lifetime of the first interconnection structure is about 10 times of a lifetime of a single interconnection structure. Changes in Vg and Vg′ represent degradation of R4, so that accurate changes in the impedance of the single interconnection structure can be obtained, and the degradation condition of the single interconnection structure is explored to obtain accurate failure time of the single interconnection structure, thereby improving the accuracy of predicting the characteristic life of components and the whole system.

An embodiment of the present disclosure further provides an interconnection structure impedance measurement method applied to the interconnection structure impedance measurement device as shown in FIG. 8. As shown in FIG. 10, the interconnection structure impedance measurement method includes the following operations S11 to S14.

At operation S11, providing a first current for the interconnection structure impedance measurement circuit.

In this operation, the constant current source provides a first current to the interconnection structure impedance measurement circuit.

At operation S12, controlling the interconnection structure impedance measurement circuit to be in a first state, and detecting a first voltage between the first branch and the second branch; where in the first state, the first switch and the second switch are closed and the third switch is open.

In this step, the control module controls to close the first switch K1 and the second switch K2 and open the third switch K3, and measures an inter-bridge voltage Vg with a voltmeter.

At operation S13, controlling the interconnection structure impedance measurement circuit to switch from the first state to a second state, and detecting a second voltage between the first branch and the third branch: where in the second state, the first switch and the third switch are closed and the second switch is open.

In this operation, the control module controls to close the first switch K1 and the third switch K3 and open the second switch K2, and measures an inter-bridge voltage Vg′ with a voltmeter. In the first and second states, the constant current source is in a measurement mode.

At operation S14, stopping providing the first current for the interconnection structure impedance measurement circuit, and calculating an impedance of the first interconnection structure and an impedance of the second interconnection structure according to the first resistor, the second resistor, the third resistor, the fourth resistor, the first voltage, the second voltage and the first current.

In this operation, the constant current source is off, and the control module solves for R3 and R4 through equations (5) and (6).

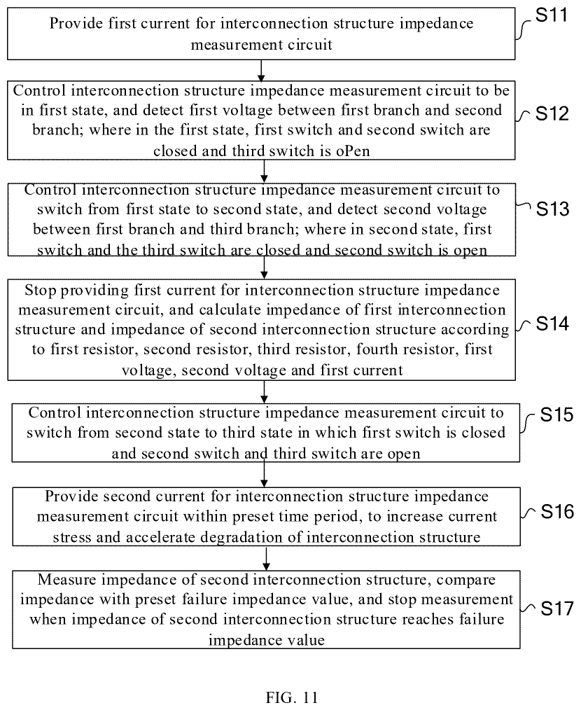

An embodiment of the present disclosure further provides an interconnection structure impedance measurement method for reliability testing, where the method is applied to the interconnection structure impedance measurement device as shown in FIG. 9, and, as shown in FIG. 11, includes the following operations S11 to S17.

At operation S11, providing a first current for the interconnection structure impedance measurement circuit.

At operation S12, controlling the interconnection structure impedance measurement circuit to be in a first state, and detecting a first voltage between the first branch and the second branch; where in the first state, the first switch and the second switch are closed and the third switch is open.

At operation S13, controlling the interconnection structure impedance measurement circuit to switch from the first state to a second state, and detecting a second voltage between the first branch and the third branch: where in the second state, the first switch and the third switch are closed and the second switch is open.

At operation S14, stopping providing the first current for the interconnection structure impedance measurement circuit, and calculating an impedance of the first interconnection structure and an impedance of the second interconnection structure according to the first resistor, the second resistor, the third resistor, the fourth resistor, the first voltage, the second voltage and the first current.

At operation S15, controlling the interconnection structure impedance measurement circuit to switch from the second state to a third state in which the first switch is closed and the second switch and the third switch are open.

In this operation, the control module controls to close the first switch K1, and open the second switch K2 and the third switch K3.

At operation S16, providing a second current for the interconnection structure impedance measurement circuit within a preset time period, to increase current stress and accelerate degradation of the interconnection structure.

In this operation, the control module controls the constant current source to switch to a power supply mode to provide the desired current stress. In the power supply mode, the current flowing through the first branch is greater than that in the measurement mode.

At operation S17, measuring an impedance of the second interconnection structure, comparing the impedance with a preset failure impedance value, and stopping measurement when the impedance of the second interconnection structure reaches the failure impedance value.

The failure impedance value is a resistance failure standard value, and in this operation, operations S11 to S14 are repeated until the impedance of the second interconnection structure reaches the failure standard, and then the measurement is ended.

In some embodiments, the interconnection structure impedance measurement method further includes: recording failure time from the beginning of supplying the second current to the end of the measurement; and performing reliability analysis on the second interconnection structure according to the failure time.

In reliability testing, changes in the resistance value are desired to be monitored continuously for most occasions. According to the interconnection structure impedance measurement scheme provided in the embodiments of the present disclosure, not only the initial resistance value of the impedance is measured, but also accurate measurement of tiny impedance changes generated during the testing are implemented, and the accurate failure time can be obtained according to the preset failure standard, which is very important for reliability predictive analysis.

In an electromigration reliability experiment, since the microelectronic product is under an action of current stress for a long time in the application process, there will be metal atoms displaced along an electron movement direction, especially in an interconnection structure, which may lead to failures, such as holes, fracture and the like, in the interconnection structure, and thus increased impedance of the interconnection structure and even an open circuit, causing damage to the whole device or product. With the development of miniaturization in the field of microelectronics, the interconnection structure has continuously reduced size, constantly increased current density, and more aggravated electromigration. Therefore, the electromigration reliability testing before the product is put into actual application is more and more necessary, while evaluation of the electromigration reliability of a single interconnection structure is key of the electromigration reliability testing. Due to a relatively low impedance of the single interconnection structure, changes in the impedance are hard to capture, which poses a great challenge to the accuracy of the electromigration reliability testing. However, with the interconnection structure impedance measurement scheme provided in the embodiments of the present disclosure, not only an initial value of the single interconnection structure impedance can be measured, but also variations of the impedance can be accurately monitored, so that the problem existing in the electromigration reliability testing of the single interconnection structure can be solved.

The embodiments of the present disclosure can monitor the impedance of the single interconnection structure in the reliability experiment, and monitor the impedance of the interconnection structure in real time and measure a tiny resistance. Each interconnection structure impedance measurement circuit is a core part for accurate measurement, where a measurement sample is communicated with the interconnection structure impedance measurement circuit, a constant current source is used to supply power, a voltmeter is used to measure a voltage difference between branches, and then voltage measurement iteration is performed again to calculate the impedance of the sample to be measured through equations (5) and (6). By switching the branch switches, the impedance of the interconnection structure can be measured in real time.

The embodiments of the present disclosure may be applied to rapid detection of a packaging bonding process technology, including interconnection pads, interconnection metal lines and the like, to reflect stability of the bonding process by analyzing the measured impedance: or may be applied to reliability experiments of important components containing the interconnection structure, to obtain failure time of the interconnection structure by monitoring the impedance in real time, and thus predict the characteristic life of components or the whole system. Especially for electromigration reliability testing, the solutions provided in the embodiments of the present disclosure have been applied to life evaluation of package pads in a CPU project. The method can also be applied to some impedance measurement devices for accurate measurement of tiny impedances.

Those of ordinary skill in the art will appreciate that all or some operations of the above described method, functional modules/units in the apparatus may be implemented as software, firmware, hardware, and suitable combinations thereof. In a hardware implementation, the division between the functional modules/units mentioned in the above description does not necessarily correspond to the division of physical components: for example, one physical component may have multiple functions, or one function or operation may be performed cooperatively by several physical components. Some or all physical components may be implemented as software executed by a processor, such as a CPU, a digital signal processor or microprocessor, or implemented as hardware, or implemented as an integrated circuit, such as an application specific integrated circuit. Such software may be distributed on a computer-readable medium which may include a computer storage medium (or non-transitory medium) and communication medium (or transitory medium). The term computer storage medium includes volatile and nonvolatile, removable and non-removable media implemented in any method or technology for storage of information such as computer-readable instructions, data structures, program modules or other data, as is well known to those of ordinary skill in the art. The computer storage medium includes, but is not limited to, an RAM, an ROM, an EEPROM, a flash or any other memory technology, a CD-ROM, a digital versatile disk (DVD) or any other optical disk storage, a magnetic cartridge, a magnetic tape, a magnetic disk storage or any other magnetic storage device, or may be any other medium used for storing the desired information and accessible by a computer. Moreover, it is well known to those ordinary skilled in the art that a communication medium typically includes a computer-readable instruction, a data structure, a program module, or other data in a modulated data signal, such as a carrier wave or other transport mechanism, and may include any information delivery medium.

The present disclosure has disclosed exemplary embodiments, and although specific terms are employed, they are used and should be interpreted merely in a generic and descriptive sense, not for purposes of limitation. In some instances, as would be apparent to one skilled in the art, features, characteristics and/or elements described in connection with a particular embodiment may be used alone or in combination with features, characteristics and/or elements described in connection with another embodiment, unless expressly stated otherwise. It will, therefore, be understood by those skilled in the art that various changes in form and details may be made therein without departing from the scope of the present disclosure as set forth in the appended claims.

1. An interconnection structure impedance measurement circuit, comprising: a first branch, a second branch and a third branch connected in parallel, wherein the first branch comprises a first interconnection structure, a second interconnection structure and a first switch connected in series, the second branch comprises a first resistor, a second resistor and a second switch connected in series, and the third branch comprises a third resistor, a fourth resistor and a third switch connected in series; and
an impedance of the first interconnection structure and an impedance of the second interconnection structure are determined from a first voltage between the first branch and the second branch, a second voltage between the first branch and the third branch, the first resistor, the second resistor, the third resistor, the fourth resistor, and a first current introduced into the interconnection structure impedance measurement circuit,
wherein the first voltage is detected when the first switch and the second switch are closed and the third switch is open, and the second voltage is detected when the first switch and the third switch are closed and the second switch is open.

2. The interconnection structure impedance measurement circuit according to claim 1, wherein the first resistor has a resistance value that is not equal to a resistance value of the third resistor, and the second resistor has a resistance value that is not equal to a resistance value of the fourth resistor.

3. The interconnection structure impedance measurement circuit according to claim 1, wherein the first interconnection structure and the second interconnection structure are connected to a printed circuit board (PCB), and the interconnection structure impedance measurement circuit is disposed on the PCB, or on an interconnection structure impedance measurement device.

4. The interconnection structure impedance measurement circuit according to claim 1, wherein the first interconnection structure comprises at least two fifth resistors connected in parallel and having the same resistance value which is the same as a resistance value of the second interconnection structure; or
the first interconnection structure is a wire.

5. The interconnection structure impedance measurement circuit according to claim 4, wherein the first interconnection structure comprises n fifth resistors connected in parallel, where n is an integer greater than or equal to 2; and
the resistance value of the second resistor is n times the resistance value of the first resistor, and the resistance value of the fourth resistor is n times the resistance value of the third resistor.

6. An interconnection structure impedance measurement device, comprising: a constant current source, a voltage detection module, a control module and the interconnection structure impedance measurement circuit of claim 1, wherein
the constant current source is connected to the first branch, the second branch and the third branch, and configured to provide, under the condition that the first switch and the second switch are closed and the third switch is open, or that the first switch and the third switch are closed and the second switch is open, a first current for the interconnection structure impedance measurement circuit;
the voltage detection module is connected with the first branch, the second branch and the third branch, respectively, and configured to detect, under the condition that the first switch and the second switch are closed and the third switch is open, a first voltage between the first branch and the second branch; and detect, under the condition that the first switch and the third switch are closed and the second switch is open, a second voltage between the first branch and the third branch; and
the control module is configured to control the constant current source to provide the first current for the interconnection structure impedance measurement circuit, and control the closing or opening of the first switch, the second switch, and the third switch; and acquire the first voltage and the second voltage detected by the voltage detection module, and calculate an impedance of the first interconnection structure and an impedance of the second interconnection structure according to the first resistor, the second resistor, the third resistor, the fourth resistor, the first voltage, the second voltage and the first current.

7. The interconnection structure impedance measurement device according to claim 6, wherein the first interconnection structure comprises at least two fifth resistors connected in parallel and having the same resistance value which is the same as a resistance value of the second interconnection structure or the first interconnection structure is a wire; and
the constant current source is further configured to provide a second current for the interconnection structure impedance measurement circuit under the condition that the first switch is closed and the second switch and the third switch are open, wherein the second current is greater than the first current.

8. An interconnection structure impedance measurement method applied to the interconnection structure impedance measurement device of claim 6, the method comprising:
providing a first current for the interconnection structure impedance measurement circuit;
controlling the interconnection structure impedance measurement circuit to be in a first state, and detecting a first voltage between the first branch and the second branch; wherein in the first state, the first switch and the second switch are closed and the third switch is open;
controlling the interconnection structure impedance measurement circuit to switch from the first state to a second state, and detecting a second voltage between the first branch and the third branch; wherein in the second state, the first switch and the third switch are closed and the second switch is open; and
stopping providing the first current for the interconnection structure impedance measurement circuit, and calculating an impedance of the first interconnection structure and an impedance of the second interconnection structure according to the first resistor, the second resistor, the third resistor, the fourth resistor, the first voltage, the second voltage and the first current.

9. An interconnection structure impedance measurement method applied to the interconnection structure impedance measurement device of claim 7, the method comprising:
measuring the impedance of the second interconnection structure;
controlling the interconnection structure impedance measurement circuit to switch from the second state to a third state in which the first switch is closed and the second switch and the third switch are open;
providing a second current for the interconnection structure impedance measurement circuit within a preset time period, to increase current stress and accelerate degradation of the interconnection structure; and
measuring the impedance of the second interconnection structure, comparing the impedance with a preset failure impedance value, and stopping measurement when the impedance of the second interconnection structure reaches the failure impedance value,
wherein the measuring the impedance of the second interconnection structure comprises:
providing a first current for the interconnection structure impedance measurement circuit;
controlling the interconnection structure impedance measurement circuit to be in a first state, and detecting a first voltage between the first branch and the second branch; wherein in the first state, the first switch and the second switch are closed and the third switch is open;
controlling the interconnection structure impedance measurement circuit to switch from the first state to a second state, and detecting a second voltage between the first branch and the third branch; wherein in the second state, the first switch and the third switch are closed and the second switch is open; and
stopping providing the first current for the interconnection structure impedance measurement circuit, and calculating an impedance of the first interconnection structure and an impedance of the second interconnection structure according to the first resistor, the second resistor, the third resistor, the fourth resistor, the first voltage, the second voltage and the first current.

10. The method according to claim 9, further comprising:
recording failure time from the beginning of supplying the second current to the end of the measurement; and
performing reliability analysis on the second interconnection structure according to the failure time.

11. The interconnection structure impedance measurement circuit according to claim 4, wherein the first resistor has a resistance value that is not equal to a resistance value of the third resistor, and the second resistor has a resistance value that is not equal to a resistance value of the fourth resistor.

12. The interconnection structure impedance measurement circuit according to claim 4, wherein the first interconnection structure and the second interconnection structure are connected to a printed circuit board (PCB), and the interconnection structure impedance measurement circuit is disposed on the PCB, or on an interconnection structure impedance measurement device.

13. The interconnection structure impedance measurement circuit according to claim 5, wherein the first resistor has a resistance value that is not equal to a resistance value of the third resistor, and the second resistor has a resistance value that is not equal to a resistance value of the fourth resistor.

14. The interconnection structure impedance measurement circuit according to claim 5, wherein the first interconnection structure and the second interconnection structure are connected to a printed circuit board (PCB), and the interconnection structure impedance measurement circuit is disposed on the PCB, or on an interconnection structure impedance measurement device.

15. The interconnection structure impedance measurement device according to claim 6, wherein the first resistor has a resistance value that is not equal to a resistance value of the third resistor, and the second resistor has a resistance value that is not equal to a resistance value of the fourth resistor.

16. The interconnection structure impedance measurement device according to claim 6, wherein the first interconnection structure and the second interconnection structure are connected to a printed circuit board (PCB), and the interconnection structure impedance measurement circuit is disposed on the PCB, or on an interconnection structure impedance measurement device.

17. The interconnection structure impedance measurement device according to claim 6, wherein the first interconnection structure comprises at least two fifth resistors connected in parallel and having the same resistance value which is the same as a resistance value of the second interconnection structure; or
the first interconnection structure is a wire.

18. The interconnection structure impedance measurement device according to claim 17, wherein the first interconnection structure comprises n fifth resistors connected in parallel, where n is an integer greater than or equal to 2; and
the resistance value of the second resistor is n times the resistance value of the first resistor, and the resistance value of the fourth resistor is n times the resistance value of the third resistor.

19. The interconnection structure impedance measurement device according to claim 7, wherein the first interconnection structure comprises n fifth resistors connected in parallel, where n is an integer greater than or equal to 2; and
the resistance value of the second resistor is n times the resistance value of the first resistor, and the resistance value of the fourth resistor is n times the resistance value of the third resistor.
